(19) United States
(12) Patent Application Publication
(10) Pub. No.: US 2004/0099875 A1
(43) Pub. Date: May 27, 2004

(54) Structure of surface mount device light emitting diode

(76) Inventor: Jung Kan Lin, Gueishan Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/662,289

(22) Filed: Sep. 16, 2003

(30) Foreign Application Priority Data
Nov. 26, 2002 (TW) 91219020

(51) Int. Cl. H01L 27/15

(52) U.S. Cl. 257/100; 257/99

(57) ABSTRACT

The invention provides a structure of Surface Mount Device Light Emitting Diode (SMD LED), which includes a printed circuit board with a metal reflection cup set concavely on the printed circuit board. Besides, at least one LED chip is bonded to the metal reflection cup and electrically connected to the printed circuit board. In addition, an encapsulant is utilized to cover the LED chip and also protrudes from the surface of the printed circuit board for forming a desired shape. The encapsulant of the invention can be directly molded on the printed circuit board and integrally formed in any shape so that the encapsulant will not come off the printed circuit board in any circumstances and that the metal reflection cup can let the light to be fully reflected.

### BACKGROUND OF THE INVENTION

1. Field of the Invention

The invention relates to a Surface Mount Device Light Emitting Diode (SMD LED) and, more particularly, to a SMD LED that will not come off the printed circuit board and allows the light to be fully reflected.

2. Description of the Related Art

The Surface Mount Device Light Emitting Diode (SMD LED) is an electronic device for emitting light when in conduction as well as a light-emitting device for fabricating semiconductor material. The lifespan of a SMD LED can be longer than a hundred thousand hours. In fact, the SMD LED has been widely employed as a light source for information electronic products, which have a tendency toward miniaturization, due to the following properties of the SMD LED: small in volume, low in power consumption, no idling time, fast in response, durable for shock proofing, low in contamination, and suitable for mass production. Besides, the SMD LED can be fabricated to be extremely small or an array-like device for adapting to various applications.

A conventional SMD LED, as shown in FIG. 1 and FIG. 2, is to form a plastic reflection cup 12 on a substrate 10 that is usually a metal sheet. Besides, a LED chip 14 is bonded to the plastic reflection cup 12, and the LED chip 14 utilizes a metal lead frame 16 to electrically connect to the substrate 10. In addition, an epoxy 18 wraps the LED chip 14, and a layer of UV epoxy 20 is applied to the epoxy 18 for adhering a hemisphere-shaped plastic encapsulant 22.

The SMD LED utilizes materials with different expansion coefficient and contraction coefficient for joining, but the position shifting between different materials after joining will be increased due to temperature differences between the materials. The increasing in position shifting tends to result in a fault or slit between materials after joining. Specifically, when performing the SMD solder reflow, the hemisphere-shaped plastic encapsulant 22 will prone to come off more easily. Unfortunately, the plastic reflection cup 12 is the only thing contained inside the conventional SMD LED. Therefore, the light reflection effect is not good enough.

Focusing on the above-mentioned problem, the invention provides a new structure of SMD LED capable of efficiently coping with the conventional drawback.

### SUMMARY OF THE INVENTION

The main and first object of the invention is to provide a structure of SMD LED, and the encapsulant of the SMD LED is directly molded on the printed circuit board and integrally formed in a desired shape so that it is unnecessary to additionally adhere any other encapsulant of the desired shape on the printed circuit board and that the encapsulant can be prevented from coming off in any circumstances.

The second object of the invention is to provide a structure of SMD LED, which is to form a metal reflection cup on the printed circuit board so that by using the metal reflection cup, the light can be fully reflected to get a better effect in light convergence.

The third object of the invention is to provide a structure of SMD LED, which is to utilize different materials with the same or similar expansion coefficient and contraction coefficient for joining so that the position shifting between the materials caused by the temperature difference can be reduced to a minimum or a zero.

To achieve the aforementioned objects, the invention is to provide a metal reflection cup set concavely on a printed circuit board, wherein at least one LED chip is bonded to the metal reflection cup and electrically connected to the printed circuit board; and also provide an encapsulant that is formed over the LED chip and protrudes from the surface of the printed circuit board for forming a desired shape.

The objects and technical contents of the invention will be better understood through the description of the following embodiments with reference to the drawings.

### BRIEF DESCRIPTION OF THE DRAWINGS

FIG. 1 is a sectional view of a conventional structure.

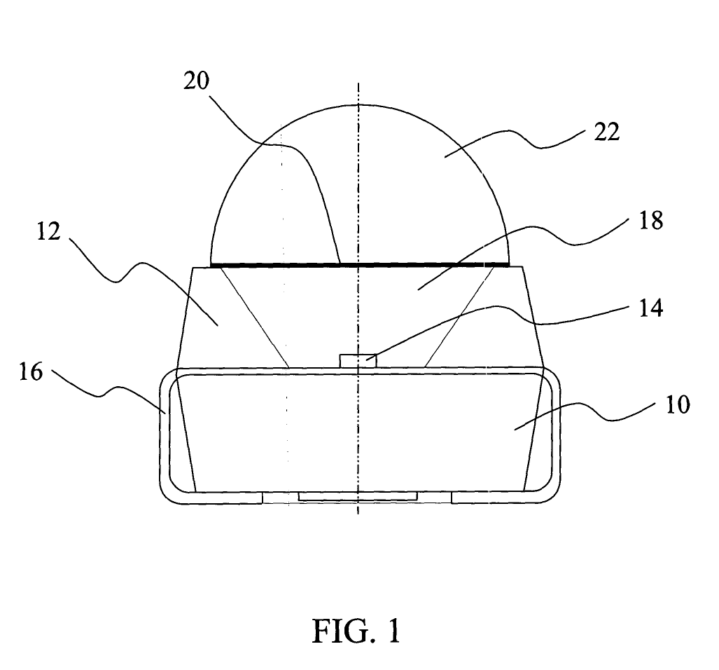

FIG. 2 is a top view of a conventional structure.

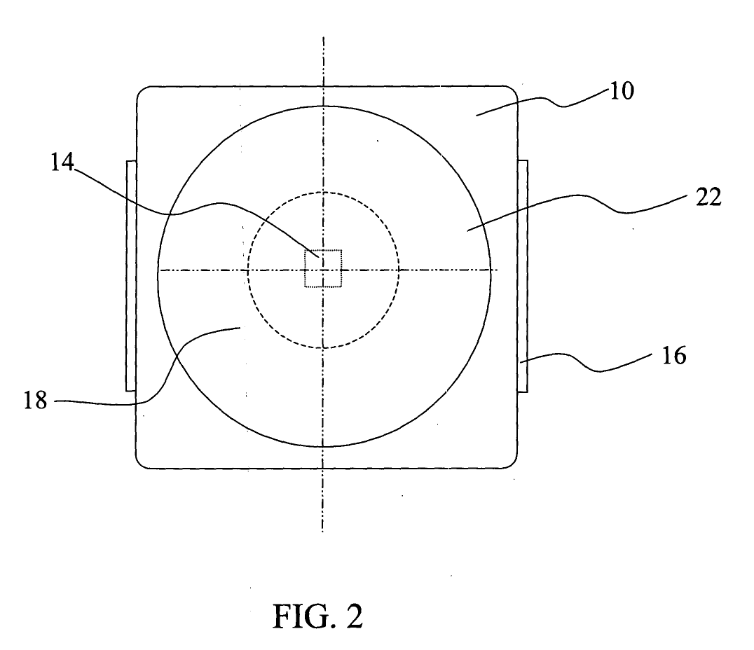

FIG. 3 is a sectional view of the structure of the invention.

FIG. 4 is a top view of the structure of the invention.

### DETAILED DESCRIPTION OF THE PREFERRED EMBODIMENTS

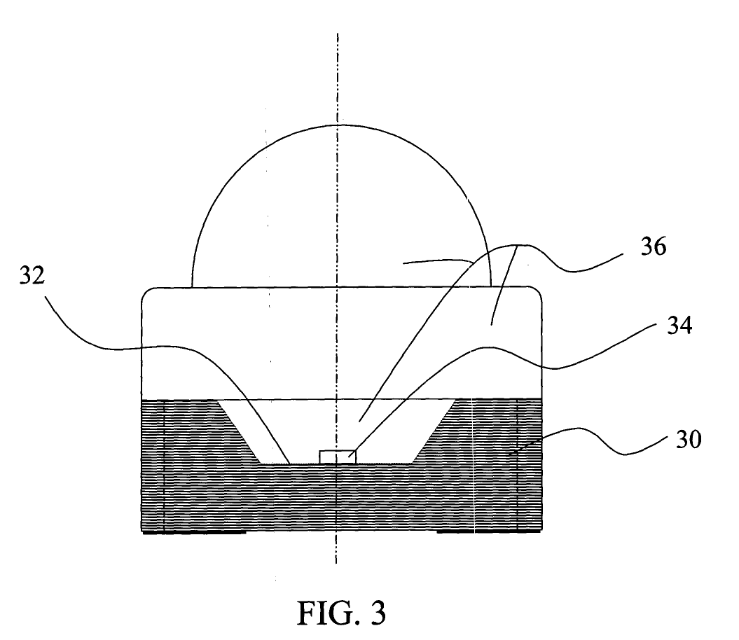

A structure of SMD LED, as shown in FIG. 3, includes a printed circuit board 30 with a metal reflection cup 32 set concavely on the printed circuit board 30. Besides, a LED chip 34 is bonded to the metal reflection cup 32 and electrically connected to the printed circuit board 30. In addition, an encapsulant 36 is used to cover the LED chip 34 and also protrudes from the surface of the printed circuit board 30 for forming a hemisphere shape. Also, the encapsulant 36 is an epoxy.

The printed circuit board 30 and the encapsulant 36 are two materials with the same or similar expansion coefficient and contraction coefficient. Therefore, when performing a bonding, the position shifting between the two materials caused by the temperature difference can be reduced to a minimum or even a zero. Also, the encapsulant 36 is directly molded on the printed circuit board 30 and integrally formed in the shape of a hemisphere, a cylinder, or an ellipse. By doing so, it is unnecessary to additionally bond the hemisphere-shaped plastic encapsulant 36 to the printed circuit board 30, as what is done in the prior art. Therefore, when executing the SMD solder reflow later, the situation that the hemisphere-shaped plastic encapsulant 36 coming off the printed circuit board 30 will not happen. In addition, the encapsulant 36 can be directly printed on the printed circuit board 30 with a variety of shapes. The metal reflection cup 32 on the printed circuit board 30 allows the light to be fully reflected and obtain a better effect in light convergence.

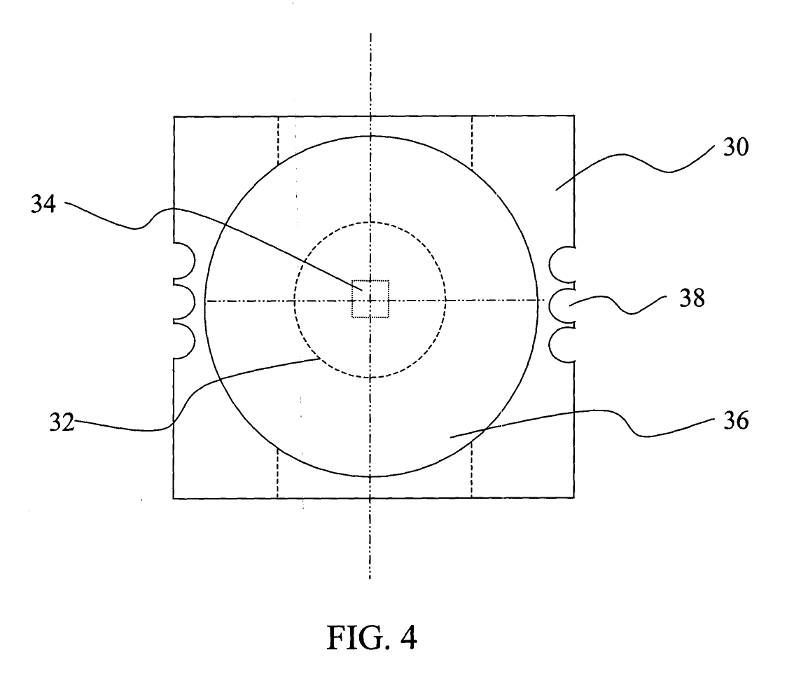

In particular, as shown in FIG. 4, a single or a plurality of grooves 38 is provided on each of the two sides of the printed circuit board 30 in order that the executing of the SMD solder reflow can be more convenient.

In conclusion, the invention is to provide a structure of SMD LED, whose encapsulant is directly molded on the printed circuit board for forming various shapes without additionally adhering any other encapsulant of the desired shape on the printed circuit board so that the encapsulant can be prevented from coming off in any circumstances. Besides, the printed circuit board and the encapsulant have similar materials; therefore, the position shifting between the materials caused by the temperature difference will not be increased. Finally, the metal reflection cup designed on the printed circuit board allows the light to be fully reflected and therefore obtain a better effect in light convergence.

The embodiments above are only intended to illustrate the invention; they do not, however, to limit the invention to the specific embodiments. Accordingly, various modifications and changes may be made without departing from the spirit and scope of the invention-as described in the appended claims.

What is claimed is:

1. A structure of Surface Mount Device Light Emitting Diode (SMD LED), including:
a printed circuit board with a metal reflection cup set concavely on the printed circuit board;
at least one LED chip bonded onto the metal reflection cup and electrically connected to the printed circuit board; and
an encapsulant that is formed over the LED chip and protrudes from the surface of the printed circuit board for forming a desired shape.

2. The structure of SMD LED as claimed in claim 1, wherein the printed circuit board and the encapsulant are composed of two-materials that have the same or similar expansion coefficient and contraction coefficient.

3. The structure of SMD LED as claimed in claim 1, wherein the encapsulant can be formed in the shape of a hemisphere, a cylinder, an ellipse, or any other shape.

4. The structure of SMD LED as claimed in claim 1, wherein a molding method is used for forming the encapsulant so that the encapsulant can be formed in any shape during the molding.

5. The structure of SMD LED as claimed in claim 1, wherein the encapsulant is an epoxy or the like.

6. The structure of SMD LED as claimed in claim 1, wherein a single or a plurality of grooves is provided at each of the two sides of the printed circuit board.
